(19) United States
(12) Patent Application Publication
(10) Pub. No.: US 2003/0155582 A1
(43) Pub. Date: Aug. 21, 2003

(54) Gate dielectric structures for integrated circuits and methods for making and using such gate dielectric structures

(76) Inventors: Maitreyee Mahajani, Saratoga, CA (US); Andrew J. Walker, Mountain View, CA (US); Igor G. Kouznetsov, Santa Clara, CA (US)

Correspondence Address: MATRIX SEMICONDUCTOR, INC., 3230 SCOTT BOULEVARD, SANTA CLARA, CA, 95034, US

(21) Appl. No.: 10/079,472

(22) Filed: Feb. 19, 2002

(51) Int. Cl. H01L 31/0328

(52) U.S. Cl. 257/200

(57) ABSTRACT

Gate dielectric structures for integrated circuits and methods for manufacturing such gate dielectric structures are described. The gate dielectric structures contain gate oxide layers that are provided using a low temperature in-situ steam generation process, thereby providing silicon oxide layers of a very high quality. The gate oxide layers are used primarily in thin film transistors and as the bottom layer in the gate dielectric of silicon-oxide-nitride-oxide-silicon semiconductor devices.

FIELD OF THE INVENTION

The invention generally relates to methods for fabricating integrated circuits (ICs) and the resulting structures. More particularly, the invention relates to gate dielectric structures used in IC manufacturing and methods for making such structures. Even more particularly, the invention relates to gate oxides used in thin film transistors and silicon-oxide-nitride-oxide-silicon semiconductor devices.

BACKGROUND OF THE INVENTION

Many integrated circuits contain dielectric materials that are used in the various layers and films comprising the device. One commonly employed dielectric material is silicon dioxide (SiO₂), often referred to as silicon oxide. Silicon oxide materials—especially when of a high quality—are often used in the gate oxide (or gate dielectric) layers in transistors because of their superior dielectric properties.

The physical characteristics of such oxide layers are an important consideration when manufacturing an integrated circuit, such as thin film transistors (TFTs) and semiconductor devices. The thickness and quality of the gate oxide layer used in TFTs and as the bottom oxide (also known as the tunneling oxide) and in silicon-oxide-nitride-oxide-silicon (SONOS) semiconductor devices are important to efficient performance of the device. In TFT devices, for example, the gate dielectric structure typically contains 10-100 Å of SiO₂ grown on top of an underlying channel layer typically made of polysilicon. In SONOS devices, the device contains a stack of the following layers: a first silicon oxide layer grown over a first silicon layer; a silicon nitride layer deposited over the first silicon oxide layer; a second silicon oxide layer deposited on the silicon nitride layer; and a second polysilicon layer deposited over the second silicon oxide layer. The oxide-nitride-oxide layers are part of the gate dielectric structure.

There are many conventional methods for making silicon oxide layers to be used as gate oxides. One conventional method is rapid thermal oxide (RTO) where a silicon layer or substrate is quickly heated at a high temperature in an oxidizing atmosphere. Another conventional method is furnace oxidation where a silicon layer or substrate is heated in an oxidizing atmosphere. Yet another conventional method is plasma oxidation where a silicon layer or substrate is exposed to oxygen (O₂) plasma. Other conventional methods—such as atomic layer oxide deposition—deposit the oxide layer, rather than grow the oxide layer through an oxidation process.

One conventional method currently under investigation is known as in-situ steam generation (ISSG) oxidation process. So far, conventional ISSG processes have been investigated for manufacturing ultra-thin dielectrics for deep submicron CMOS semiconductor devices. See, for example, U.S. Pat. Nos. 6,184,155 and 6,323,143. Thus, adoption of ISSG processing for gate oxides has been quite limited, especially for TFT and SONOS devices.

SUMMARY OF THE INVENTION

The invention provides gate dielectric structures for integrated circuits and methods for manufacturing the same. The gate dielectric structures contain gate oxide layers that are provided using a low temperature in-situ steam generation process, thereby providing silicon oxide layers of a very high quality. The gate oxide layers are used primarily in thin film transistors and as the bottom layer in the gate dielectric of silicon-oxide-nitride-oxide-silicon semiconductor devices.

BRIEF DESCRIPTION OF THE DRAWINGS

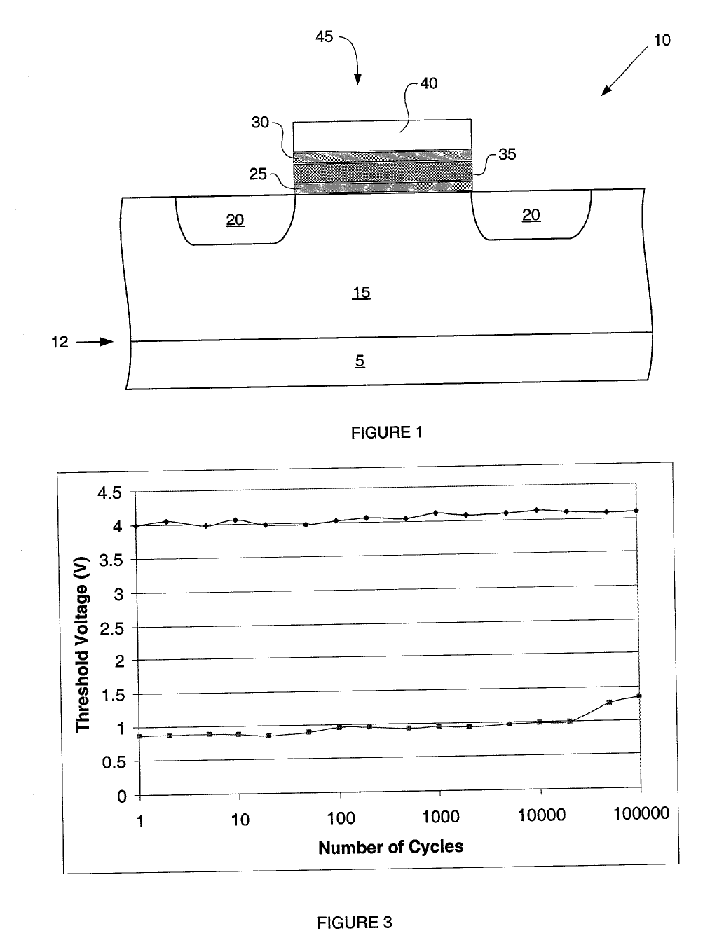

FIGS. 1, 2a, 2b, and 3 are views of one aspect of the gate dielectric structures and methods of making the same according to the invention, in which:

FIG. 1 illustrates one aspect of the invention in a SONOS transistor;

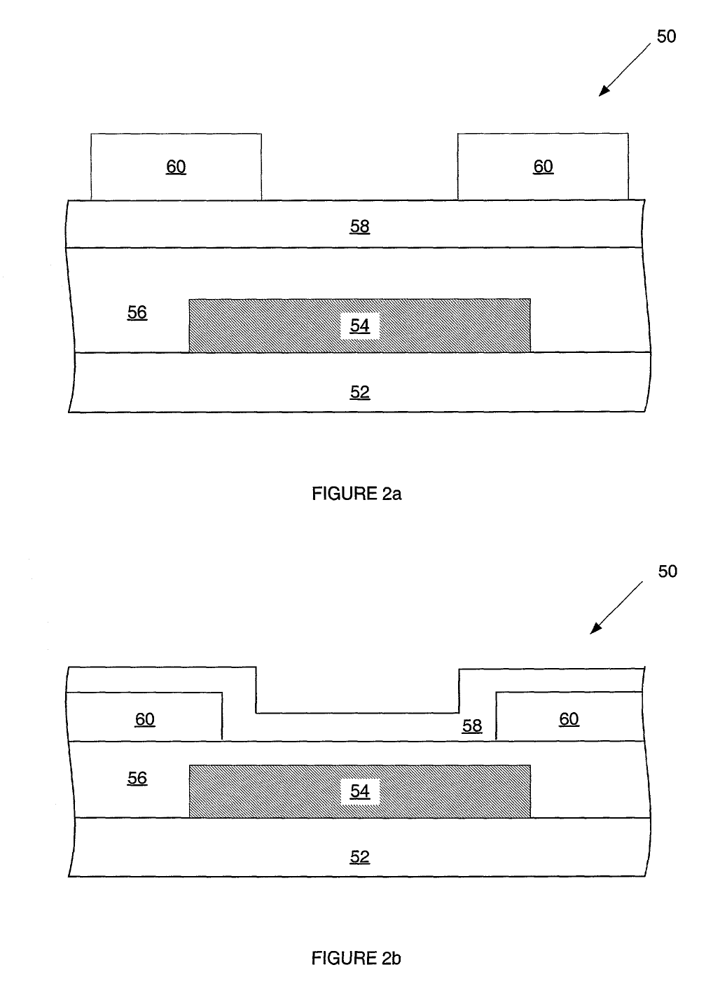

FIGS. 2a and 2b illustrate another aspect of the invention in two different thin film transistor devices; and

FIG. 3 depicts the endurance characteristics of the devices in one aspect of the invention.

FIGS. 1, 2a, 2b, and 3 presented in conjunction with this description are views of only particular—rather than complete—portions of the gate dielectric structures and methods of making the same according to the invention.

DETAILED DESCRIPTION OF THE INVENTION

The following description provides specific details in order to provide a thorough understanding of the present invention. The skilled artisan, however, would understand that the present invention can be practiced without employing these specific details. Indeed, the present invention can be practiced by modifying the illustrated structures and methods, and can be used in conjunction with apparatus and techniques conventionally used in the industry. For example, while the invention is described with reference to ISSG silicon oxide layers used in gate oxide structures, the silicon oxide layers of the invention can be used as high-quality dielectric layers in other parts of integrated circuits including antifuse oxides in devices like field programmable gate arrays.

Generally, the invention provides a gate dielectric structure containing a high-quality silicon oxide layer that is made via a low temperature ISSG process. The invention can be used in any gate dielectric structure used in integrated circuits, such as in TFT devices and in SONOS devices. In one aspect of the invention, the invention is used for gate oxide structures in TFT and SONOS-based devices.

The gate dielectric structure of the invention can be used in any SONOS based semiconductor device containing a silicon-oxide-nitride-oxide-silicon layered structure, such as SONOS transistors. A SONOS transistor has the same general configuration as an insulated gate field effect transistor (IGFET), including a gate conductor (typically of polysilicon, metal, or a silicide) separated from a semiconductor substrate (typically silicon) by a dielectric structure. This dielectric structure often includes a layer of silicon nitride sandwiched between layers of silicon oxide.

FIG. 1 depicts an exemplary SONOS transistor that can be used in one aspect of the invention. In FIG. 1, transistor 10 contains substrate 12. Any substrate known in the art can be used in the invention. Suitable substrates include silicon wafers, epitaxial Si layers, polysilicon layers, bonded wafers such as used in silicon-on-insulator (SOI) technologies, and/or amorphous silicon layers, all of which may be doped or undoped.

In one aspect of the invention, the substrate 12 in the invention is a single crystal silicon wafer 5 having at least one epitaxial (“epi”) Si layer 15 located in an upper region thereof. If desired, more than one epitaxial layer can be provided on the upper surface. The epitaxial layer(s) can be provided using any known process in the art, including any known epitaxial deposition process. The epitaxial layer(s) can remain undoped or can be doped with a desired dopant to the desired concentration using any suitable process known in the art.

Transistor 10 also contains gate structure 45. Gate structure 45 comprises gate conducting layer 40 and—as known in the art—an comprise any suitable material that can be used as a gate conductor, such as metal, silicide, or polysilicon. In the aspect of the invention where the integrated device is a SONOS transistor, the gate conductor is preferably polysilicon. If desired, the conductive layer 40 can be doped with any suitable dopant to the desired concentration, e.g., with P or B to a concentration of between about 1×10²⁰ to about 1×10²¹ atoms/cm³.

Transistor 10 also contains source and drain regions 20 that are separated by the width of the gate structure 45. As known in the art, source and drains regions have been implanted with a suitable dopant to obtain the desired profile and concentration. Any dopant known in the art can be employed in the invention depending on the desired type of conductivity, e.g., p-type or n-type. Examples of suitable dopants include such as arsenic, boron, phosphorus, aluminum, antimony, bismuth, thallium, indium, gallium, or a combination of these dopants. In one aspect of the invention, the dopant concentration can range from about 1×10¹⁹ to about 1×10²¹ atoms/cm³.

In the aspect of the invention illustrated in FIG. 1, the dielectric structure contains an “ONO dielectric” separating the gate conductor 40 from substrate 12. The ONO dielectric structure comprises a first oxide layer 25, a nitride layer 35, and a second oxide layer 30. Conventionally, in SONOS devices, the first oxide layer is formed by a rapid thermal oxidation (RTO) or furnace oxidation as described above. This oxidation is typically followed by a nitridation process to form nitride layer 35. In the method of the invention, however, the first oxide layer is formed using a low temperature ISSG process.

The ISSG process used in the invention is carried out by placing the substrate 12 in a suitable chemical vapor deposition (CVD) apparatus. In one aspect of the invention, the CVD apparatus comprises a low pressure CVD apparatus, preferably one containing a single wafer chamber. The pressure of the LPCVD chamber can range from about 100 millitorr to about 760 torr, and is preferably about 7 torr.

The substrate is then heated to a temperature sufficient to perform the ISSG process. In one aspect of the invention, the temperature ranging from about 750 to about 1050 degrees Celsius and preferably the temperature is about 950 degrees Celsius. A suitable gas mixture is then introduced into the CVD apparatus and flowed over the substrate surface. A suitable gas mixture is any mixture containing oxygen and hydrogen, preferably introduced separately into the CVD chamber. Other inert or non-reactive gases (such as argon or helium) can be included in the gas mixture, but need not be present.

The flow rate of the oxygen and hydrogen in the ISSG process is optimized to obtain the desired growth of the oxide layer. In one aspect of the invention, the oxygen flow rate can range from about 1 to about 5 liters/minute, preferably about 2-4 liters/minute, and more preferably about 3 liters/minute. In one aspect of the invention, the hydrogen flow rate can range from about 20 to about 1000 sccm (standard cubic centimeters/minute), preferably about 20 to about 100 sccm, and more preferably about 50 sccm.

This oxidation process is continued for a time sufficient to form a high-quality oxide layer with the desired thickness. In one aspect of the invention, the thickness of the oxide layer formed by the ISSG process can range from about 10 to about 200 angstroms, preferably about 10 to about 50 angstroms, and more preferably about 25 angstroms. As the deposition rate of the ISSG process described above can range from about 0.5 to about 2 angstroms/second, the time for the oxidation can range from about 10 seconds to about 100 seconds.

If desired, this oxidation process can be followed by an annealing process. Any suitable annealing process known in the art that maintains the quality of the oxide layer can be employed in the invention. In one aspect of the invention, the annealing process is performed in a nitrogen and oxygen atmosphere, such as nitric oxide (NO), to form an oxynitride and improve the quality and reliability of the oxide layer.

The annealing process is typically carried out in any CVD apparatus capable of performing the annealing process under the conditions detailed herein. In one aspect of the invention, the CVD apparatus comprises a single wafer chamber operating near atmospheric pressure, e.g., a pressure ranging from about 10 millitorr to about 760 torr. The annealing process is performed at temperature ranging from about 700 to about 1000 degree Celsius, and is preferably performed at about 800 degrees Celsius. The flow rate of the NO in the annealing process is optimized to obtain the desired growth of the oxynitride layer. In one aspect of the invention, the NO flow rate can range from about 0.5 to about 5 liters/minute, and is preferably about 2 liters/minute.

This annealing process is continued for a time sufficient to form the oxynitride layer with the desired thickness and to anneal the underlying oxide layer. In one aspect of the invention, the thickness of the oxynitride layer formed by the annealing process can range from about 2 to about 10 angstroms, and is preferably about 2 to about 3 angstroms. The deposition rate of the annealing process is extremely slow and strongly depends on temperature and starting oxide thickness. For example, at a temperature of 800 degrees Celsius and with an oxide thickness of 16 angstroms, a 2 angstrom thickness oxynitride layer is formed only after 240 seconds. As well, the annealing process is self-limiting and, therefore, the oxynitride thickness does not grow linearly with time.

After the ISSG process is concluded, the remainder of the SONOS transistor is manufactured as known in the art. This further processing would include forming the nitride layer 35, second oxide layer 30, gate conductor 40, source and drain regions 20 as known in the art.

In another aspect of the invention, the ISSG process can be used to form the oxide layer in the gate dielectric structures of TFT devices. TFT devices are similar to semiconductor devices, yet do not use a crystalline silicon substrate. The gate dielectric structures of the invention can be used in any TFT device, including floating gate flash transistors, and TFT SONOS transistors. Exemplary TFT devices are illustrated in FIGS. 2a and 2b.

FIG. 2a illustrates a top-contact type of TFT device while FIG. 2b illustrates a bottom-contact type of TFT device. In both FIGS. 2a and 2b, the TFT devices 50 contain any suitable substrate 52 as known in the art. Suitable substrates include those made from materials other than crystalline Si such as sapphire, amorphous silicon, and glass-based materials. In one aspect of the invention, glass materials are used as substrate 52.

Both the TFT devices illustrated in FIGS. 2a and 2b have a gate conductor 54. The gate conductor can comprise any suitable material that can be used as a gate conductor in the TFT device, such as metal, silicide, or polysilicon. In the aspect of the invention illustrated in FIGS. 2a and 2b, gate conductor 54 comprises polysilicon.

The TFT devices in FIGS. 2a and 2b contain semiconducting layer 58, as well as source and drain electrodes 60, all of which are well known in the art. The TFT devices in FIGS. 2a and 2b also contain insulating layer 56. The insulating layer 56 is a gate dielectric layer such as a gate oxide of a high quality similar to that described above for the SONOS device. The gate oxide in the TFT device also has a similar thickness ranging from about 10 to about 200 angstroms.

The gate oxide of the TFT device is made in the invention using substantially the same ISSG process described above (i.e., that described for SONOS devices) except that for TFT devices, the oxide is grown over polysilicon. Thus, the growth rates will be more than the growth rates described above for SONOS devices. Accordingly, lower process temperatures and/or shorter times will be required for TFT devices to obtain a similar oxide thickness as SONOS devices. In one aspect of the invention, the temperature for the ISSG process used to make the gate dielectric for TFT devices can range form about 600 to about 900 degrees Celsius, preferably about 700 to about 850 degrees Celsius, and more preferably about 800 degrees Celsius.

As described above, the ISSG process can be used to form the gate oxide of a TFT device and the bottom oxide in the gate dielectric structure of a SONOS device. Using the ISSG process as described above, TFT devices can be manufactured that exhibit similar performance characteristics as CMOS devices. In particular, SONOS-based TFT devices were manufactured using the ISSG processes for the bottom oxide layer. The endurance characteristics (W/E) of these devices were then tested. The results of this test are depicted in FIG. 3. The endurance characteristics of such devices made according to the invention were then compared with the endurance characteristics of analogous SONOS-based CMOS devices. See FIG. 14 of Fujiawara et al. “0.13 μm Metal-Oxide-Nitride-Oxide-Semiconductor Single Transistor Memory Cell With Separated Source Line” Jpn. J. Appl. Phys. Vol. 39 pp. 417-423 (2000).

The comparison indicated that the endurance characteristic, which is a direct function of the oxide quality, of both types of devices was comparable. The ability to obtain such a comparable endurance characteristic illustrates the advantages of using the ISSG processes described above to make the gate oxide. Absent the ISSG processing, such TFT based devices generally would have inferior performance to analogous CMOS based devices.

Having described the preferred embodiments of the present invention, it is understood that the invention defined by the appended claims is not to be limited by particular details set forth in the above description, as many apparent variations thereof are possible without departing from the spirit or scope thereof.

We claim:

1. A method for making a thin film transistor containing a gate dielectric structure, comprising:
providing a substrate for the gate dielectric structure; and
providing an oxide layer of the gate oxide structure on the substrate by an in-situ steam generation process.

2. The method of claim 1, wherein the substrate comprises a gate conductor on a glass substrate.

3. The method of claim 1, wherein the thin film transistor is a floating gate transistor or a SONOS transistor.

4. The method of claim 1, wherein the in-situ steam generation process flows hydrogen and oxygen over the substrate.

5. The method of claim 1, wherein the in-situ steam generation process is performed at a temperature ranging from about 600 to about 900 degrees Celsius.

6. The method of claim 1, wherein the in-situ steam generation process is performed at a pressure ranging from about 100 millitorr to about 760 torr.

7. The method of claim 1, wherein the in-situ steam generation process is performed for a time sufficient to deposit an oxide thickness of about 10 to about 200 angstroms.

8. The method of claim 1, further including annealing the oxide layer in a nitric oxide atmosphere.

9. A method for making a semiconductor device, comprising:
providing a substrate;
providing a first oxide layer on the substrate by an in-situ steam generation process;
providing a nitride layer on the oxide layer; and
providing a second oxide layer on the nitride layer.

10. The method of claim 9, wherein the semiconductor devices is a SONOS transistor.

11. The method of claim 9, wherein the in-situ steam generation process flows hydrogen and oxygen over the substrate.

12. The method of claim 9, wherein the in-situ steam generation process is performed at a temperature ranging from about 750 to about 1050 degrees Celsius.

13. The method of claim 9, wherein the in-situ steam generation process is performed at a pressure ranging from about 100 millitorr to about 760 torr.

14. The method of claim 9, wherein the in-situ steam generation process is performed for a time sufficient to deposit an oxide thickness of about 10 to about 200 angstroms.

15. The method of claim 9, further including annealing the oxide layer in a nitric oxide atmosphere.

16. A method for making a gate dielectric structure for a thin film transistor or a SONOS device, comprising:
providing a substrate; and
providing an oxide layer of a gate dielectric structure on the substrate by an in-situ steam generation process.

17. The method of claim 16, wherein the in-situ steam generation process flows hydrogen and oxygen over the substrate.

18. The method of claim 16, wherein the in-situ steam generation process is performed at a pressure ranging from about 100 millitorr to about 760 torr and a temperature ranging from about 600 to about 1050 degrees Celsius.

19. The method of claim 16, wherein the in-situ steam generation process is performed for a time sufficient to deposit an oxide thickness ranging from about 10 to about 200 angstroms.

20. The method of claim 16, further including annealing the oxide layer in a nitric oxide atmosphere.

21. A method for making a gate dielectric structure for a thin film transistor or a SONOS device, comprising.
providing a substrate;
providing an oxide layer of a gate dielectric structure, the oxide layer having a thickness of about 10 to about 200 angstroms; and
annealing the oxide layer in a nitric oxide atmosphere.

22. A method for making a gate dielectric structure for a thin film transistor or a SONOS device, comprising.
providing a substrate;
providing an oxide layer of a gate dielectric structure on the substrate by an in-situ steam generation process performed at a temperature ranging from about 600 to about 1050 degrees Celsius, a pressure ranging from about 100 millitorr to about 760 torr, and for a time sufficient to deposit an oxide thickness of about 10 to about 200 angstroms; and
annealing the oxide layer in a nitric oxide atmosphere.

23. A thin film transistor containing a gate dielectric structure made by the method comprising:
providing a substrate for a gate dielectric structure; and
providing an oxide layer of the gate dielectric structure on the substrate by an in-situ steam generation process.

24. A SONOS semiconductor device made by the method comprising:
providing a substrate;
providing a first oxide layer on the substrate by an in-situ steam generation process;
providing a nitride layer on the oxide layer; and
providing a second oxide layer on the nitride layer.

25. An integrated circuit containing a thin film transistor with a gate dielectric structure made by the method comprising:
providing a substrate for the gate dielectric structure; and
providing an oxide layer of the gate dielectric structure on the substrate by an in-situ steam generation process.

26. An integrated circuit containing a SONOS semiconductor device made by the method comprising:
providing a substrate;
providing a first oxide layer on the substrate by an in-situ steam generation process;
providing a nitride layer on the oxide layer; and
providing a second oxide layer on the nitride layer.
